(19) United States
(12) Patent Application Publication
(10) Pub. No.: US 2026/0122852 A1
(43) Pub. Date: Apr. 30, 2026

(54) COMPLIANT OSCILLATING HEAT PIPE

(71) Applicant: Raytheon Company, Tewksbury, MA (US)

(72) Inventors: Edward Lawrence Hieb, Aubrey, TX (US); Travis Mayberry, Dallas, TX (US); Craig H. McCordic, Medfield, MA (US)

(21) Appl. No.: 18/925,248

(22) Filed: Oct. 24, 2024

(51) Int. Cl. H05K 7/20

(52) U.S. Cl. CPC H05K 7/2039; H05K 7/20336

(57) ABSTRACT

A heat sink is provided including: a body including: a first portion; a second portion recessed from the first portion and thermally couplable to a target structure; and a third portion between the first portion and the second portion; and a plurality of oscillating heat pipes integrally formed with the body. The plurality of oscillating heat pipes are included in the first portion, the second portion, and the third portion. The plurality of oscillating heat pipes are configured to apply a spring force in a direction perpendicular to a plane of the body.

### BACKGROUND

The present disclosure relates to heat sinks and, in particular, to a heat sinks including a compliant oscillating heat pipe.

Electronics packaging is trending towards higher heat-producing devices in smaller volumes. Ever-increasing heat flux may create challenging thermal architecture problems. Techniques which support effective heat dissipation and prevent overheating in electronic components are desired.

### BRIEF DESCRIPTION

Example embodiments of the present disclosure are directed to a heat sink including: a body including: a first portion; a second portion recessed from the first portion and thermally couplable to a target structure; and a third portion between the first portion and the second portion; and a plurality of oscillating heat pipes integrally formed with the body, wherein: the plurality of oscillating heat pipes are included in the first portion, the second portion, and the third portion; and the plurality of oscillating heat pipes are configured to apply a spring force in a direction perpendicular to a plane of the body.

In any one or combination of the embodiments disclosed herein, the plurality of oscillating heat pipes are configured to apply the spring force toward the target structure.

In any one or combination of the embodiments disclosed herein, the plurality of oscillating heat pipes are embedded in at least a portion of the body.

In any one or combination of the embodiments disclosed herein, the heat sink is configured to maintain thermal coupling between the second portion and the target structure based on the spring force.

In any one or combination of the embodiments disclosed herein, the spring force is based on a spring constant associated with the plurality of oscillating heat pipes.

In any one or combination of the embodiments disclosed herein, the heat sink is cantilever shaped; and the third portion extends in an angular direction from the first portion to the second portion.

In any one or combination of the embodiments disclosed herein, the third portion is provided in plurality; and each of the plurality of third portions extends between the first portion and the second portion.

In any one or combination of the embodiments disclosed herein, the third portion includes a spiral structure centered about an axis perpendicular to a plane of the body; and the spiral structure is configured to apply a force in the direction perpendicular to the plane of the body.

In any one or combination of the embodiments disclosed herein, a condenser region of the plurality of oscillating heat pipes is included in the first portion.

In any one or combination of the embodiments disclosed herein, an evaporator region of the plurality of oscillating heat pipes is included in the second portion.

In any one or combination of the embodiments disclosed herein, an adiabatic region of the plurality of oscillating heat pipes is included in the third portion.

In any one or combination of the embodiments disclosed herein, the body includes a thermally-conductive material.

Example embodiments of the present disclosure are directed to an apparatus including: a heat sink including: a body including: a first portion; a second portion recessed from the first portion and thermally coupled to a target structure; and a third portion between the first portion and the second portion; and a plurality of oscillating heat pipes integrally formed with the body, wherein: the plurality of oscillating heat pipes are included in the first portion, the second portion, and the third portion; and the plurality of oscillating heat pipes are configured to apply a spring force in a direction perpendicular to a plane of the body; and a layer of thermal grease between a surface of the second portion and a surface of the target structure.

In any one or combination of the embodiments disclosed herein, the plurality of oscillating heat pipes are configured to apply the spring force toward the target structure.

In any one or combination of the embodiments disclosed herein, the plurality of oscillating heat pipes are embedded in at least a portion of the body.

In any one or combination of the embodiments disclosed herein, the heat sink is configured to maintain thermal coupling between the second portion and the target structure based on the spring force.

In any one or combination of the embodiments disclosed herein, the spring force is based on a spring constant associated with the plurality of oscillating heat pipes.

In any one or combination of the embodiments disclosed herein, the heat sink is cantilever shaped; and the third portion extends in an angular direction from the first portion to the second portion.

In any one or combination of the embodiments disclosed herein, the third portion is provided in plurality; and each of the plurality of third portions extends between the first portion and the second portion.

In any one or combination of the embodiments disclosed herein, the third portion includes a spiral structure centered about an axis perpendicular to a plane of the body; and the spiral structure is configured to apply a force in the direction perpendicular to the plane of the body.

Additional features and advantages are realized through the techniques of the present disclosure. Other embodiments and aspects of the disclosure are described in detail herein and are considered a part of the claimed technical concept. For a better understanding of the disclosure with the advantages and the features, refer to the description and to the drawings.

### BRIEF DESCRIPTION OF THE DRAWINGS

For a more complete understanding of this disclosure, reference is now made to the following brief description, taken in connection with the accompanying drawings and detailed description, wherein like reference numerals represent like parts.

FIGS. 1A through 1C illustrates an example of a heat sink in accordance with one or more embodiments of the present disclosure.

FIG. 2 illustrates an example of a heat sink in accordance with another embodiment of the present disclosure.

FIGS. 3A through 3C illustrate an example of a heat sink in accordance with another embodiment of the present disclosure.

FIG. 4 illustrates a comparative example of a heat sink in accordance with some other approaches.

### DETAILED DESCRIPTION

A detailed description of one or more embodiments of the disclosed apparatus and method are presented herein by way of exemplification and not limitation with reference to the Figures.

In accordance with one or more embodiments of the present disclosure, a heat sink is provided that uses integrated oscillating heat pipes (OHP) embedded within the body of the heat sink. In some aspects, a heated region (also referred to herein as an evaporator region) of the OHP is attached affixed to appendages that have a spring-like function. A transport region (also referred to herein as an adiabatic region) of the OHP is embedded within the appendages, providing a connection to a cooling region (also referred to herein as a condenser region) of the heatsink located further away from the heated region.

In some aspects, the spring-like action provided by the heat sink improves effectiveness of the compliant OHP, for example, due to the increased compression on the surface of a target component (e.g., a component generating heat) in contact with the heat sink. The spring-like action provided by the heat sink may may mitigate the reliance on a thick gap-filler material of some other approaches.

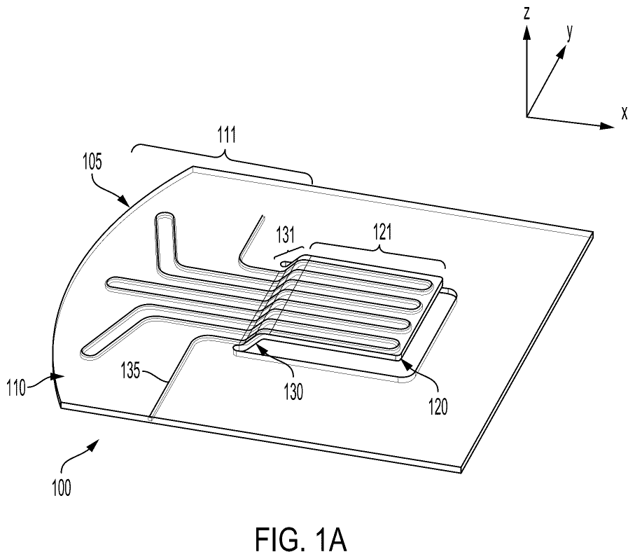

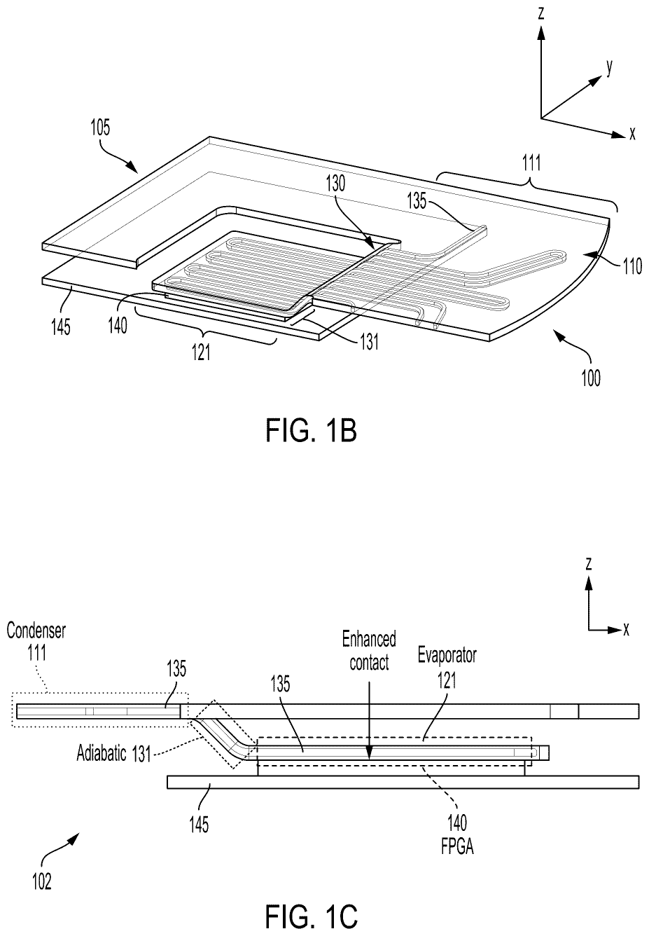

FIGS. 1A through 1C illustrates an example of a heat sink in accordance with one or more embodiments of the present disclosure.

With reference to FIGS. 1A through 1C, in accordance with one or more embodiments of the present disclosure, the heat sink 100 includes a body 105. The body 105 includes a first portion 110, a second portion 120, and a third portion 130, in which the third portion 130 extends between the first portion 110 and the second portion 120.

In some aspects, the second portion 120 is recessed (e.g., in the Z-direction) from the first portion 110. In accordance with one or more embodiments of the present disclosure, the second portion 120 may be thermally coupled to a target structure 140 included on a circuit board 145.

The heat sink 100 includes oscillating heat pipes 135 integrally formed with the body 105. In accordance with one or more embodiments of the present disclosure, the oscillating heat pipes 135 are embedded in at least a portion of the body 105. For example, the oscillating heat pipes 135 may be included in the first portion 110, the second portion 120, and the third portion 130.

The oscillating heat pipes 135 are configured to apply a spring force in a direction (e.g., Z-direction) perpendicular or substantially perpendicular to a plane of the body 105. In accordance with one or more embodiments of the present disclosure, the heat pipes 135 are configured to apply the spring force toward the target structure 140.

Accordingly, for example, the heat sink 100 is configured to maintain thermal coupling between the second portion 120 and the target structure 140 based on the spring force. In some aspects, the spring force is based on a spring constant associated with the plurality of oscillating heat pipes 135. Embodiments of the present disclosure support tuning or configuring aspects of the heat sink 100 in association with providing the spring force. For example, embodiments of the present disclosure support configuring the shape, configuration, and/or materials of each oscillating heat pipe 135 (e.g., based on statics and structural mechanics) in association with providing a target spring constant. In some examples, embodiments of the present disclosure support configuring a quantity or configuration of the oscillating heat pipes 135 in association with providing a target spring constant by the oscillating heat pipes 135 (and accordingly, for example, the heat sink 100).

The term “substantially,” as used herein, means approximately or actually. The term “substantially perpendicular” means approximately or actually perpendicular. The term “substantially parallel” means approximately or actually parallel.

The target structure 140 may be an FPGA, an ASIC, another electrical component, a non-electrical component, or the like, and is not limited thereto. The target structure 140 may be an electronic component mounted in an electronic enclosure (not illustrated), but is not limited thereto. In some examples, the heat sink 100 may be mounted to or fixed within the electronic enclosure.

With reference to the example of FIGS. 1A through 1C, the heat sink 100 may be cantilever shaped, but is not limited thereto. For example, the third portion 130 may extend in an angular direction from the first portion 110 to the second portion 120.

In the example of FIGS. 1A through 1C, a condenser region 111 of the oscillating heat pipes 135 is included in the first portion 110, an evaporator region 121 of the oscillating heat pipes 135 is included in the second portion 120, and an adiabatic region 131 of the oscillating heat pipes 135 is included in the third portion 130.

Example aspects of features provided by the oscillating heat pipes 135 as described herein. In the evaporator region 121, heat (e.g., from the target structure 140) may be absorbed by liquid segments, and tails of the liquid segments may change into a vapor (vapor state). Vapor segments adjacent to the liquid may expand. Portions of the liquid which carry heat may be pushed by the vapor segments to the condenser region 111, for example, via the adiabatic region 131.

In the condenser region 111, heat is removed from liquid segments. In the condenser region 111, vapor condenses back into a liquid, and adjacent liquid segments rejoin. Accordingly, for example, at the condenser region 111, vapor segments may shrink based on the removal of heat from the liquid segments and the vapor.

The vapor, as described herein, moves liquid to and from the condenser region 111 and the evaporator region 121. The example events described with reference to the oscillating heat pipes 135 may occur simultaneously across one or more serpentine passes (e.g., several serpentine passes) included among the oscillating heat pipes 135 and induce a chaotic oscillatory motion.

Embodiments of the present disclosure support forming the body 105 of a thermally-conductive material supportive of features of the heat sink 100 described herein. For example, the body 105 may be formed of materials such as, for example, metals, ceramics, polymers, or the like, and the oscillating heat pipes 135 may be formed of, for example, channel features within the parent body that are absent of the body material or embedded tube, where the channel volume is filled with a working fluid.

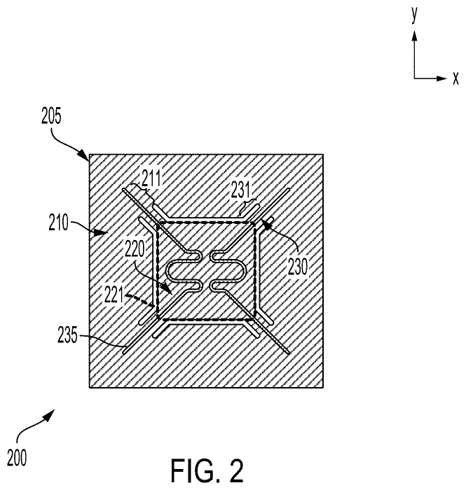

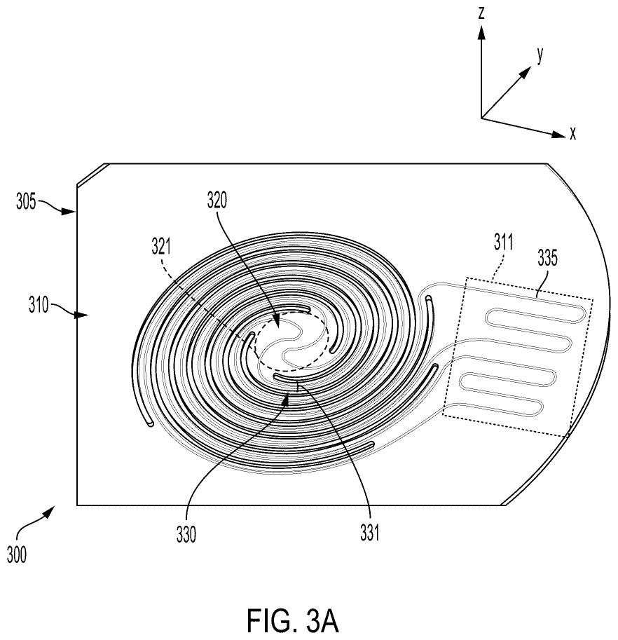

FIG. 2 illustrates an example of a heat sink 200 in accordance with another embodiment of the present disclosure. The heat sink 200 may include aspects of the heat sink 100, and repeated descriptions of like elements are omitted for brevity.

With reference to the example of FIG. 2, the heat sink 200 includes a body 205. The body 205 includes a first portion 210, a second portion 220, and a third portion 230. The third portion 230 is provided in plurality.

In some aspects, the second portion 220 is recessed (e.g., in the Z-direction) from the first portion 210. For example, each of the third portions 230 angularly extends (e.g., in the Z-direction) between the first portion 210 and the second portion 220. In accordance with one or more embodiments of the present disclosure, the second portion 220 (e.g., a bottom surface of the second portion 220 in the z-direction) may be thermally coupled to a target structure 140.

The heat sink 200 may include oscillating heat pipes 235 in the first portion 210, the second portion 220, and the third portions 230.

In the example of FIG. 2, condenser regions 211 of the oscillating heat pipes 235 may be included in the first portion 210, an evaporator region 221 of the oscillating heat pipes 235 may be included in the second portion 220, and adiabatic regions 231 of the oscillating heat pipes 235 may be respectively included in the third portions 230.

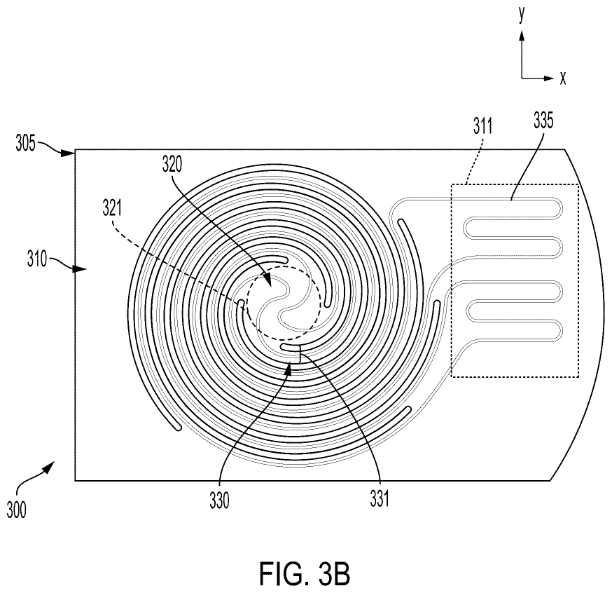

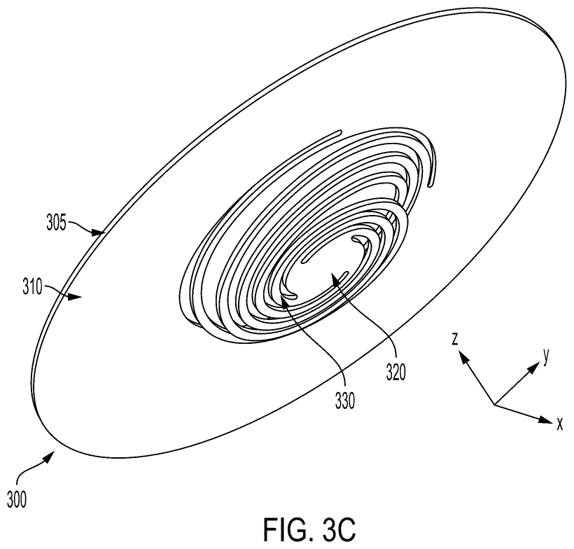

FIGS. 3A through 3C illustrate an example of a heat sink 300 in accordance with another embodiment of the present disclosure. The heat sink 300 may include aspects of the heat sink 100 and/or heat sink 200, and repeated descriptions of like elements are omitted for brevity.

With reference to the example of FIGS. 3A through 3C, the heat sink 300 includes a body 305. The body 305 includes a first portion 310, a second portion 320, and a third portion 330. The third portion 330 is provided in plurality.

In some aspects, the second portion 320 is recessed (e.g., in the Z-direction) from the first portion 310. For example, each of the third portions 330 may be at a height (e.g., in the Z-direction) between the first portion 310 and the second portion 320. In accordance with one or more embodiments of the present disclosure, the second portion 320 (e.g., a bottom surface of the second portion 320 in the Z-direction) may be thermally coupled to a target structure 140.

The heat sink 300 may include oscillating heat pipes 335 in the first portion 310, the second portion 320, and the third portions 330. In some embodiments, one or more of the third portions 330 may include a respective oscillating heat pipe 335. In some embodiments, each of the third portions 330 may include a respective oscillating heat pipe 335.

The third portions 130 may be included in a spiral structure centered about an axis (e.g., Z-axis) perpendicular to a plane of the body 305. The spiral structure is configured to apply a force in the direction perpendicular to the plane of the body 305.

The spiral structure may include any quantity of spirals suitable for providing features of the heat sink 300, and embodiments of the present disclosure are not limited to the quantity illustrated at FIGS. 3A through 3C.

In the example of FIGS. 3A through 3C, a condenser region 311 of the oscillating heat pipes 335 may be included in the first portion 310, an evaporator region 321 of the oscillating heat pipes 335 may be included in the second portion 320, and adiabatic regions 331 of the oscillating heat pipes 335 may be respectively included in the third portions 330. In the example of FIG. 3C, the oscillating heat pipes 335 are not illustrated.

Aspects of the embodiments described herein support effective heat dissipation for electrical components (e.g., FPGAs, ASICs, and the like). For example, some FPGAs may dissipate a relatively high amount of heat (e.g., about 100 W or more) for a 2″ square area. Embodiments of the present disclosure support implementing a heat sink (e.g., heat sink 100, heat sink 200, heat sink 300) described herein in applications including electrical components (e.g., FPGAs, ASICs, and the like) for processing on smart electronics systems. Embodiments of the present disclosure address problems of some other approaches, as FPGAs may be fragile to over-exertion from over-application of thermal interface materials (TIM) gap filler paste in such other approaches.

Aspects of the heat sink provided herein provide improvements with respect to benefits package SWAP[C] (size, weight, and power, [cost]). For example, aspects of the heat sinks provided herein may be implemented with a thinner plane compared to a liquid cold plate, provide a higher heat transfer coefficient compared to conduction alone, and provide a lightweight conformal design instead of chunky bosses. In some aspects, the implementations described herein may bring oscillating heat pipes (e.g., oscillating heat pipes 135, oscillating heat pipes 235, oscillating heat pipes 335) closer to a respective heat source (e.g., target structure 140).

Embodiments of a heat sink described herein provide a spring feature with routing singular or plural heat pipe channels (e.g., oscillating heat pipes 135, and the like) through the compliant springing appendages (e.g., third portion 130, and the like) that are connected to the same body (e.g., body 105, and the like) as the larger parent cold wall/heat spreader. As described herein, the casing/body of the heat pipes described herein are designed such that the heat pipes themselves are configured to apply a spring force sufficient for maintaining thermal contact resistance between a surface of a heat sink (e.g., a bottom surface of the second portion 120 of heat sink 100, a bottom surface of second portion 220 of heat sink 200, or a bottom surface of the second portion 320 of heat sink 300) and a target structure in association with cooling the target structure.

Based on the implementations described herein, a heat sink is provided in which a relatively thin layer of thermal grease (compared to some other approaches) resides between a hot surface of a target structure (e.g., target structure 140) and a surface of the heat sink (e.g., heat pipe contact, a bottom surface of the second portion 120 of heat sink 100).

In contrast with some other approaches, the heat sinks described herein may be provided as a singular piece including embedded oscillating heat pipes, rather than as a separate assembled raiser. Other approaches may include mounting pre-formed heat pipe risers and straps (assembly of parts) bridging to cold plates to make closer contact to components and to transfer the heat. Some other heat pipe implementations include heat pipes formed of polymer, which limits the ability of such heat pipes to perform structurally and against working pressures (i.e., vacuum and full evaporation).

Aspects of the heat sinks described herein provide effective heat transfer and cooling for applications associated with, for example, RF products, computers, electronic products including dense electronics packaging, and FPGAs.

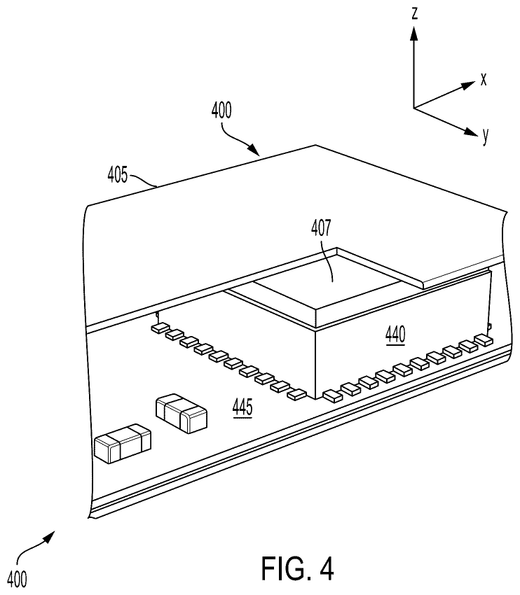

FIG. 4 illustrates a comparative example of a heat sink 400 in accordance with some other approaches. The heat sink 400 includes a body 405 thermally coupled to a target component 440 (e.g., an FPGA) via a TIM gap filler 407. In the comparative example, for heated components (e.g., target component 440) that are to be cooled with heat pipe devices, the TIM gap filler 407 may be a relatively thick thermal interface material gap pad for achieving proper thermal contact to the cold wall. The TIM gap filler 407 may introduce undesired thermal resistance, which may have problem characteristics such as, for example, relatively low thermal conductivity (e.g., 5 wpm). For cases of a silicone-based material, the TIM gap filler 407 may suffer from compression-set, loss of function over time, which may degrade surface contact between the body 405 and the target component 440. Further, for example, the thickness of the TIM gap filler 407 may disadvantageously increase the overall size of a device enclosure which includes the body 405, the TIM gap filler 407, and the target component 440, and a circuit board 445.

The term “about” is intended to include the degree of error associated with measurement of the particular quantity based upon the equipment available at the time of filing the application.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

While the present disclosure has been described with reference to an exemplary embodiment or embodiments, it will be understood by those skilled in the art that various changes may be made and equivalents may be substituted for elements thereof without departing from the scope of the present disclosure. In addition, many modifications may be made to adapt a particular situation or material to the teachings of the present disclosure without departing from the essential scope thereof. Therefore, it is intended that the present disclosure not be limited to the particular embodiment disclosed as the best mode contemplated for carrying out this present disclosure, but that the present disclosure will include all embodiments falling within the scope of the claims.

The corresponding structures, materials, acts and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the technical concepts in the form disclosed. Many modifications and variations will be apparent to those of ordinary skill in the art without departing from the scope and spirit of the disclosure. The embodiments were chosen and described in order to best explain the principles of the disclosure and the practical application and to enable others of ordinary skill in the art to understand the disclosure for various embodiments with various modifications as are suited to the particular use contemplated.

While the various embodiments to the disclosure have been described, it will be understood that those skilled in the art, both now and in the future, may make various improvements and enhancements which fall within the scope of the claims which follow. These claims should be construed to maintain the proper protection for the disclosure first described.

What is claimed is:

1. A heat sink comprising:
a body comprising:
a first portion;
a second portion recessed from the first portion and thermally couplable to a target structure; and
a third portion between the first portion and the second portion; and
a plurality of oscillating heat pipes integrally formed with the body, wherein:
the plurality of oscillating heat pipes are comprised in the first portion, the second portion, and the third portion; and
the plurality of oscillating heat pipes are configured to apply a spring force in a direction perpendicular to a plane of the body.

2. The heat sink of claim 1, wherein the plurality of oscillating heat pipes are configured to apply the spring force toward the target structure.

3. The heat sink of claim 1, the plurality of oscillating heat pipes are embedded in at least a portion of the body.

4. The heat sink of claim 1, wherein the heat sink is configured to maintain thermal coupling between the second portion and the target structure based on the spring force.

5. The heat sink of claim 1, wherein the spring force is based on a spring constant associated with the plurality of oscillating heat pipes.

6. The heat sink of claim 1, wherein:
the heat sink is cantilever shaped; and
the third portion extends in an angular direction from the first portion to the second portion.

7. The heat sink of claim 1, wherein:
the third portion is provided in plurality; and
each of the plurality of third portions extends between the first portion and the second portion.

8. The heat sink of claim 1, wherein:
the third portion comprises a spiral structure centered about an axis perpendicular to a plane of the body; and
the spiral structure is configured to apply a force in the direction perpendicular to the plane of the body.

9. The heat sink of claim 1, wherein a condenser region of the plurality of oscillating heat pipes is comprised in the first portion.

10. The heat sink of claim 1, wherein an evaporator region of the plurality of oscillating heat pipes is comprised in the second portion.

11. The heat sink of claim 1, wherein an adiabatic region of the plurality of oscillating heat pipes is comprised in the third portion.

12. The heat sink of claim 1, wherein the body comprises a thermally-conductive material.

13. Apparatus comprising:
a heat sink comprising:
a body comprising:
a first portion;
a second portion recessed from the first portion and thermally coupled to a target structure; and
a third portion between the first portion and the second portion; and
a plurality of oscillating heat pipes integrally formed with the body, wherein:
the plurality of oscillating heat pipes are comprised in the first portion, the second portion, and the third portion; and
the plurality of oscillating heat pipes are configured to apply a spring force in a direction perpendicular to a plane of the body; and
a layer of thermal grease between a surface of the second portion and a surface of the target structure.

14. The apparatus of claim 13, wherein the plurality of oscillating heat pipes are configured to apply the spring force toward the target structure.

15. The apparatus of claim 13, the plurality of oscillating heat pipes are embedded in at least a portion of the body.

16. The apparatus of claim 13, wherein the heat sink is configured to maintain thermal coupling between the second portion and the target structure based on the spring force.

17. The apparatus of claim 13, wherein the spring force is based on a spring constant associated with the plurality of oscillating heat pipes.

18. The apparatus of claim 13, wherein:
the heat sink is cantilever shaped; and
the third portion extends in an angular direction from the first portion to the second portion.

19. The apparatus of claim 13, wherein:
the third portion is provided in plurality; and
each of the plurality of third portions extends between the first portion and the second portion.

20. The apparatus of claim 13, wherein:
the third portion comprises a spiral structure centered about an axis perpendicular to a plane of the body; and
the spiral structure is configured to apply a force in the direction perpendicular to the plane of the body.
